(19) United States
(12) Patent Application Publication
(10) Pub. No.: US 2006/0215420 A1
(43) Pub. Date: Sep. 28, 2006

(54) Direct backlight module

(75) Inventors: Shin-Li Chen, Yuan Lin Hsien (TW); Chung-Te Lee, Hsinchu City (TW)

Correspondence Address: BIRCH STEWART KOLASCH & BIRCH, PO BOX 747, FALLS CHURCH, VA, 22040-0747, US

(73) Assignee: AU Optronics Corp.

(21) Appl. No.: 11/359,518

(22) Filed: Feb. 23, 2006

(30) Foreign Application Priority Data
Mar. 25, 2005 (TW) 94109259

(51) Int. Cl. A47F 3/00; H05K 3/36

(52) U.S. Cl. 362/631; 29/830; 29/832; 362/561

(57) ABSTRACT

A direct backlight module at least includes a light-source, a substrate, a heat source and-a heat-pipe, wherein the heat source comprises a PCB, an inventer, and a power supply. The light-source is disposed on the substrate. A bottom surface of the substrate is divided into a first predetermined portion and a second predetermined portion. The PCB is disposed in the first predetermined portion. The light-source is electrically connected with the PCB. The heat-pipe is disposed on the bottom surface of the substrate to transfer heat from the first predetermined portion to the second predetermined portion, such that the temperature distribution of the direct backlight module can be more evenly.

### FIELD OF THE INVENTION

The present invention relates to a backlight module, and particularly to a direct backlight module.

### DESCRIPTION OF THE PRIOR ART

Nowadays, the liquid crystal display (LCD) technique is getting matured and the LCDs gradually replaces the cathode ray tube (CRT) monitors. In the LCD industry, the LCD panel is one of major elements in the LCD product.

Please refer to FIG. 1, which is the exploded diagram of a prior direct backlight module. As FIG. 1 shows, numerous of light tubes 12 are arranged parallel above the substrate 14. There's a reflection sheet disposed on the substrate 14 to reflect the light emitted from the light tubes 12. The emitted light passes through a diffusion sheet 18 and reached an LCD panel 20 which is disposed above the backlight module 10, wherein the diffusion sheet 18 is used for scattering the emitted light so that a homogeneous light can be provided to the LCD panel 20.

In the art, a sealed space in the direct backlight module 10 for accommodating the light tubes 12 is formed between the substrate 14 and the diffusion sheet 18 to avoid entering of particles that may affect the lighting efficiency of the direct backlight module 10. As the FIG. 1 shows, the direct backlight module 10 further comprises numerous fixing frames 13 for fixing the light tubes above the substrate 14 with a predetermined height and avoiding the light tubes 12 to directly contact with the substrate 14. Upon such an arrangement, the temperature of the backlight module 10 can be more evenly and the light efficiency of the backlight module 10 can be substantially increased.

Please refer to FIG. 2, which shows a bottom-view diagram of the substrate illustrated in FIG. 1. The direct backlight module 10 further comprises a power supply PCB 19 disposed on the bottom surface of the substrate 14. The power supply PCB 19 is electrically connected to and thus powers the light tubes 12. As FIG. 2 shows, the bottom surface of the substrate 14 is divided into a first predetermined portion 141 and a second predetermined portion 142. The first predetermined portion 141 is designed for screw-mounting the power supply PCB 19 while the second predetermined portion 142 is designed for mounting other circuit boards. For instance, a circuit board for the LCD panel 20 can be disposed on the second predetermined portion 142.

In the art, heat dissipation is always an inherent problem within the direct backlight modules. For example, the heat produced from the light tubes 12 is one of heat sources. The heat within the direct backlight module 10 causes the luminance of the module 10 to decrease. Moreover, the heat from the power supply PCB 19 may raise some serious effects. The power supply PCB 19 is also an element that produces heat to contribute the uneven luminance of the direct backlight module 14.

Therefore, how to improve the uneven luminance due to the heat is important and necessary.

### SUMMARY OF THE INVENTION

It is an object of the present invention to provide a direct backlight module with even luminance.

It is another object of the present invention to improve the temperature distribution in the prior arts.

This invention relates to a direct backlight module at least including a light-source, a substrate, a power supply PCB and a heat-pipe. The light-source is disposed on the substrate. A bottom surface of the substrate is divided into a first predetermined portion and a second predetermined portion. The power supply PCB is disposed in the first predetermined portion. The light-source is electrically connected with the power supply PCB. The heat-pipe is disposed on the bottom surface of the substrate to transfer the generated heat from the first predetermined portion to the second predetermined portion, such that the temperature distribution of the direct backlight module can be more evenly.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is an exploded view of a typical direct backlight module;

FIG. 2 is a bottom view of the substrate of FIG. 1;

FIG. 3 is an exploded view of the direct backlight module of the present invention;

FIG. 4A is a bottom view of the direct backlight module of the present invention;

FIG. 4B presents FIG. 4A by removing the heat source;

FIG. 4C shows another arrangement of the heat-pipes in accordance with the present invention;

FIG. 4D shows a further arrangement of the heat-pipes in accordance with the present invention;

FIG. 5A shows how the heat-pipe of FIG. 4A is mounted on the substrate;

FIG. 5B is a cross section view of a deformed heat-pipe of the present invention;

FIG. 5C is a cross section view of a deformed heat-pipe in another embodiment of the present invention which involves a heat sink;

FIG. 6A is a top view of the LCD panel of FIG. 3;

FIG. 6B is a bottom view of the LCD panel of FIG. 3;

FIG. 6C is a bottom view of the direct backlight module of FIG. 3;

FIG. 7A shows temperature data of the direct backlight module without heat-pipes;

FIG. 7B shows temperature data of the direct backlight module having the heat-pipes of the present invention; and

FIG. 7C shows mean values of the data in FIG. 7A and FIG. 7B.

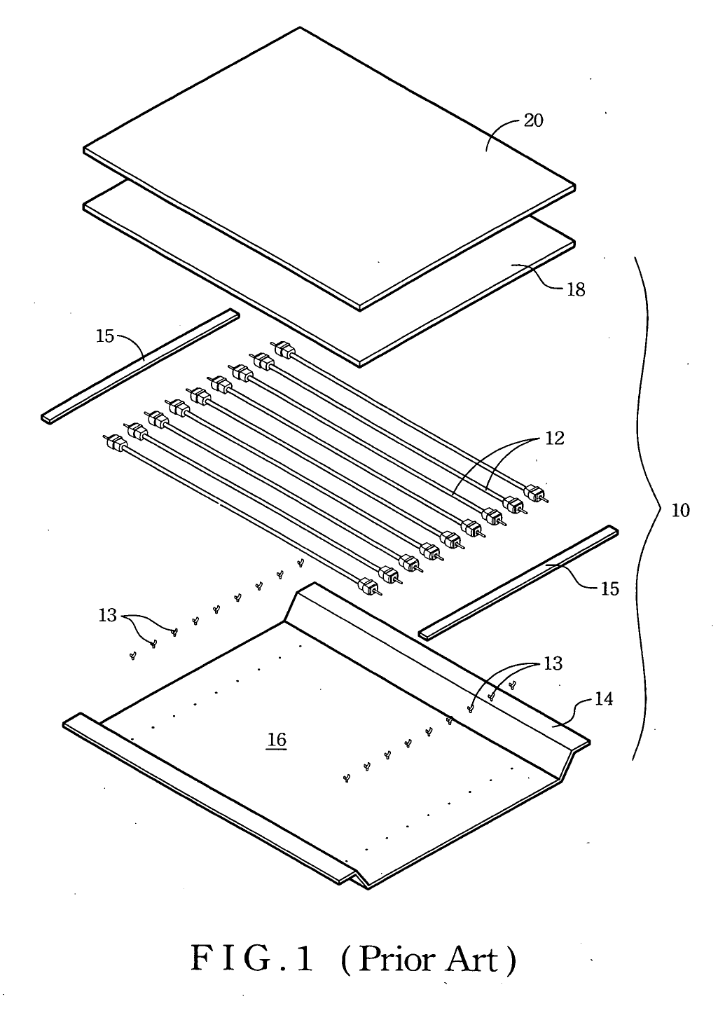

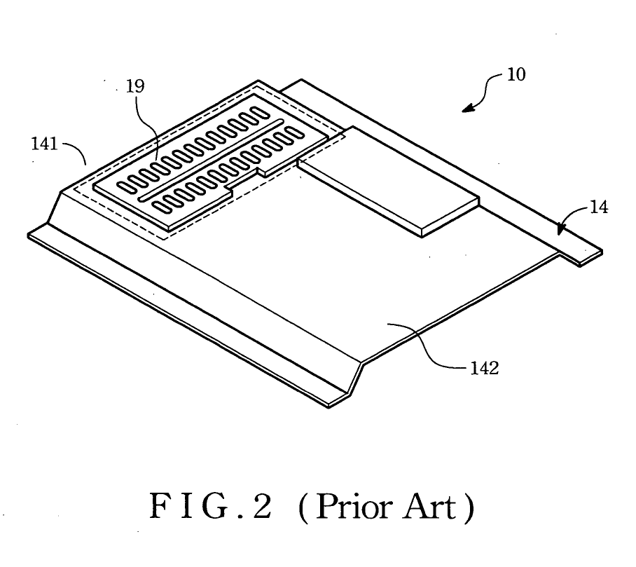

### DESCRIPTION OF THE PREFERRED EMBODIMENT

Please refer to FIG. 3, which shows the exploded structure diagram of a preferred embodiment of the direct backlight module in accordance with the present invention. As shown, a light source 32 of the direct backlight module 30 is disposed above the substrate 34. There's a reflection sheet 36 disposed on the upper surface of the substrate 34 for reflecting upward the emitted light from the light source 32. The emitted light passes through a diffusion sheet 38 and reaches an LCD panel 40 that is disposed above the backlight module 30, wherein the diffusion sheet 38 is used for scattering the emitted light so that the light leaving the diffusion sheet 38 can be much even. Herein, the light source 32 is composed of numerous of light tubes (ex. CCFL), and the light tubes are arranged above the substrate 34 parallel as shown. In other embodiments, the light source could be LED or other light elements.

The direct backlight module 30 further comprises numerous fixing frames 33 for fixing the light tubes 32 above the substrate 34 with a predetermined height to avoid touching with the substrate 34 directly.

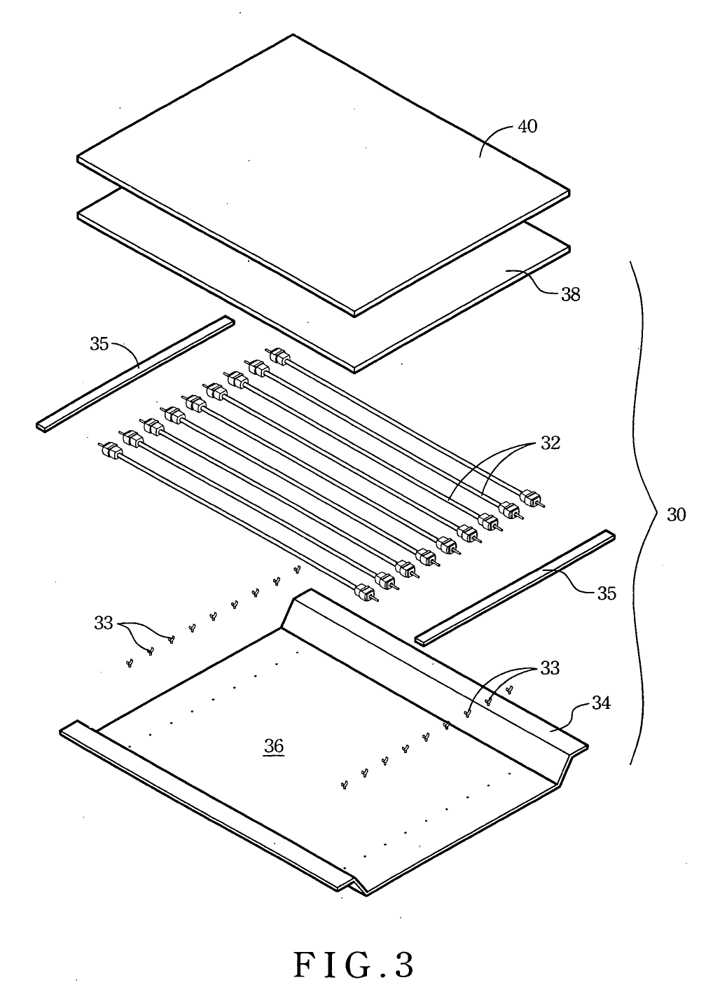

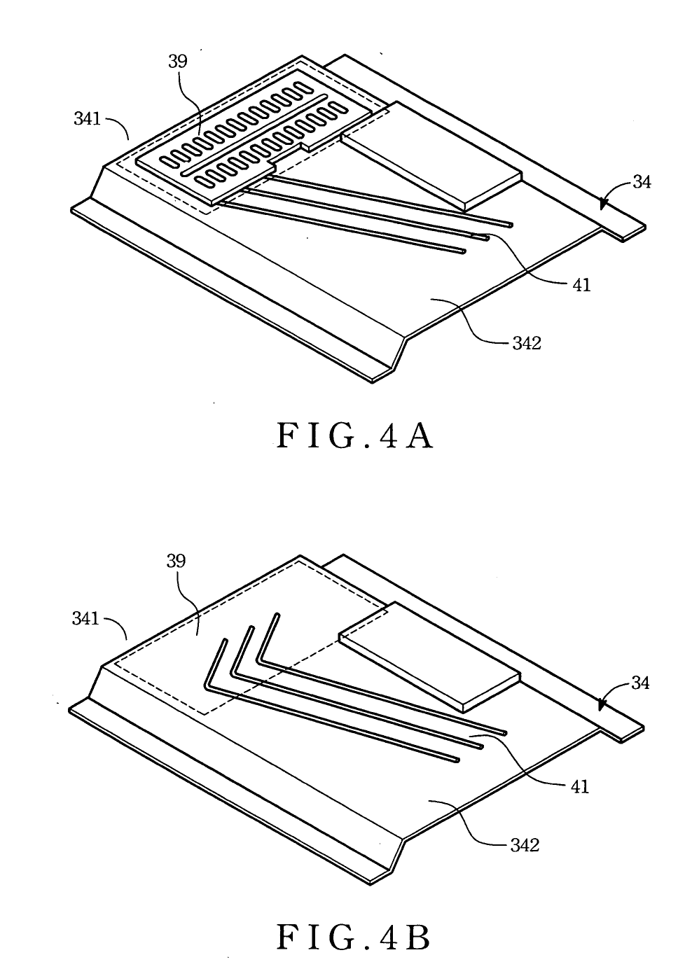

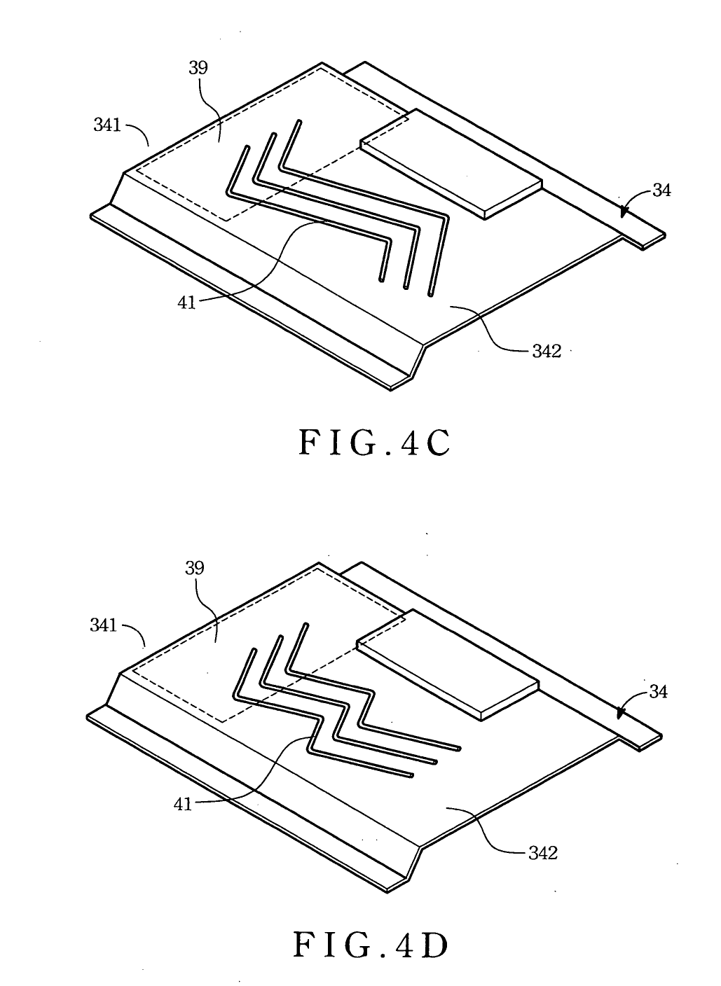

FIG. 4A is a bottom view of the substrate 34 of FIG. 3 and FIG. 4B is a diagram showing FIG. 4A with the element 39 (a heat source) removed, wherein the heat source 39 comprises a printed circuit board (PCB), an inventer, and a power supply. The direct backlight module 30 further comprises a heat source 39 and at least one heat-pipe 41 (three shown in the figures), wherein the heat source 39 and the heat-pipe 41 are disposed on the upper surface (in a figure view) of the substrate 34.

The upper surface of the substrate 34 is divided into a first predetermined portion 341 and a second predetermined portion 342. Wherein the heat source 39 is disposed on the first predetermined portion 341, wherein the heat-pipe 41 is disposed between the substrate 34 and the heat source 39 within a range corresponding to the first predetermined portion 341. The second predetermined portion 342 is left for disposing other circuit boards, for instance, the circuit board of the LCD panel 40 could be disposed on the second predetermined portion 342.

The PCB of the heat source 39 is disposed in the first predetermined portion 341 via screw-fixing and electrically connects to the light source 32.

The heat-pipe 41 is disposed on the upper surface of the substrate 34 and conducts the heat generated by PCB to the second predetermined portion 342, such that the temperature distribution of the direct backlight module 30 can be more even.

As shown in FIG. 4B, the heat-pipe 41 is disposed between the substrate 34 and the heat source 39 and is extended at both the first predetermined portion 341 and the second predetermined portion 342.

The heat-pipe 41 herein is bent to an “L” shape, such that the contact area between the heat-pipe 41 and the substrate 34 can be increased (because the bent heat-pipe 41 is longer than a non-bent one). In other embodiments of the present invention, the heat-pipe 41 can be bent into an “N” shape (shown as FIG. 4C) or a “W” shape (shown as FIG. 4D).

The embodiments shown in FIG. 4A to FIG. 4D all have three heat-pipes 41 disposed on the bottom surface of the substrate 34. However, the number of the heat-pipes 41 are not limited. The quantity of the heat-pipes 41 can vary case by case. Preferably, all heat-pipes 41 can be disposed evenly on the bottom surface of the substrate 34.

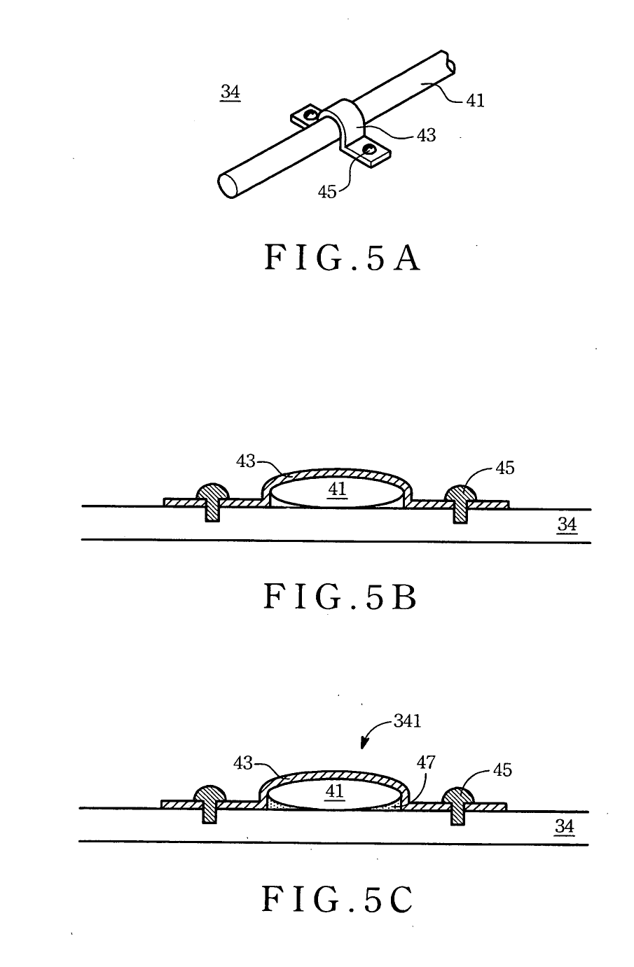

FIG. 5A is a partial enlarged diagram showing how a heat-pipe 41 is mounted on the substrate 34. Wherein the heat-pipe 41 is fixed to the bottom surface of the substrate 34 by at least one metal strip 43 and accompanying screws 45. As shown in FIG. 5B, the heat-pipe 41 may be depressed to comprise an elliptical cross section, and thus the contact area between the heat-pipe 41 and the substrate 34 can be increased (i.e., the heat conduction efficiency of the heat-pipe 41 can be enhanced).

FIG. 5C shows another embodiment that involves a heat sink. Within the range of the first predetermined portion 341 (shown in FIG. 4A to FIG. 4D), the direct backlight module 30 further comprises a heat sink 47, which is disposed on the first predetermined portion 341 and contacts both the heat-pipe 41 and the substrate 34.

The temperature of the first predetermined portion is relative higher among the bottom surface of the substrate 34 because of the existing of the heat source 39. The heat sink 47 can transfer the heat efficiently to the heat-pipe 41, and then the heat-pipe 41 can transfer the heat to the second predetermined portion that has a relative lower temperature. Therefore, the temperature distribution of the direct backlight module can be more even. The heat sink 47 can be a copper mass, an aluminum mass, or other metal mass with a high conductive coefficient. In other embodiments, a heat-conductive grease can be applied between the heat-pipe 41 and the substrate 34 for increasing the heat conduction efficiency.

The method of assembling the direct backlight module in accordance with the present invention comprises the following steps:

Providing a substrate 34, which the bottom surface of the substrate 34 is divided into the first predetermined portion 341 and the second predetermined portion 342;

Bending the heat-pipe 41 to an “L” shape, an “N” shape, or a “W” shape, and (or) deforming the heat-pipe 41 to comprise an elliptical cross section for increasing the contact area between the heat-pipe 41 and the substrate 34;

Disposing the heat-pipe 41 on the bottom surface of the substrate 34 by extending the heat-pipe 41 within the range of the first and second predetermined portions 341 and 342;

Disposing the heat sink 47 on the first predetermined portion 341 by contacting with both the heat-pipe 41 and the substrate 34; in particularly, spreading the heat conductive grease between the heat-pipe 41 and the substrate 34; and

Disposing a PCB above the first predetermined portion 341 by overlapping part of the heat-pipes 41.

The method described above is the assembling process of the bottom surface of the substrate 34, and the method of assembling the upper surface of the substrate 34 is described as follows:

Disposing the light source 32 above the substrate 34;

Electrically connecting the light source 32 and the PCB; and

Disposing the diffusion sheet 38 above the light source 332 to form a sealed space, by which particle-intruding in the space can be avoided and the lighting efficiency of the direct backlight module 30 can be ensured.

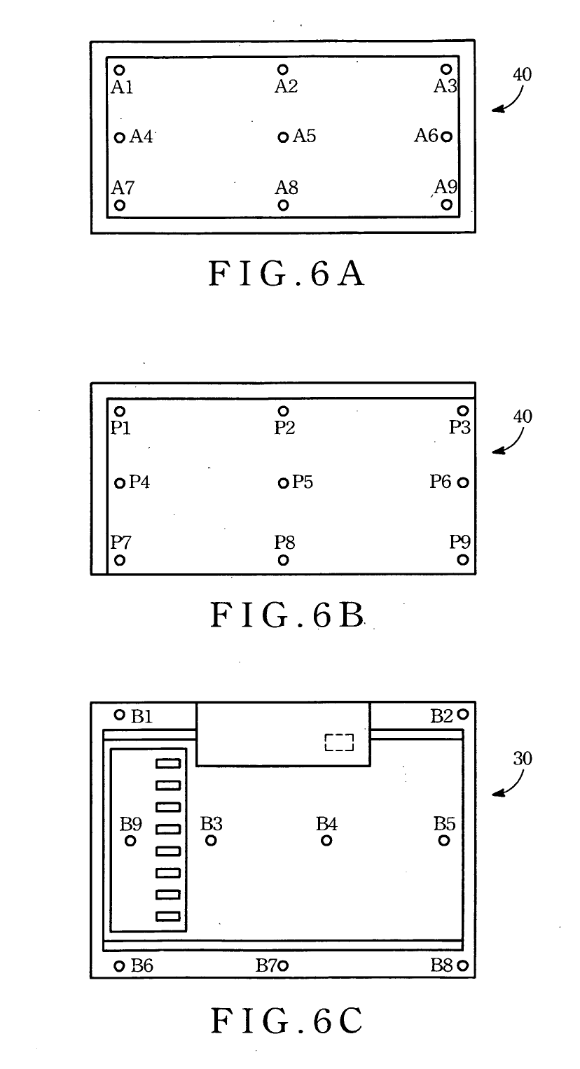

Please refer to FIG. 6A, FIG. 6B, and FIG. 6C, wherein FIG. 6A is the top view diagram of the LCD panel 40 in FIG. 3, FIG. 6B is the bottom view diagram of the LCD panel 40 in FIG. 3, and FIG. 6C is the bottom view of the direct backlight module 30 in FIG. 3. In these figures, A1-A9, P1-P9, and B1-B9 are temperature-measure points.

In the following description, a typical comparative testing is applied to a conventional LCD panel without the heat-pipes and an LCD panel having the heat-pipes of the present invention. The testing is carried out under a 27.9-° C. room temperature, and both the conventional and the present LCD panels are operated according to the same control parameters.

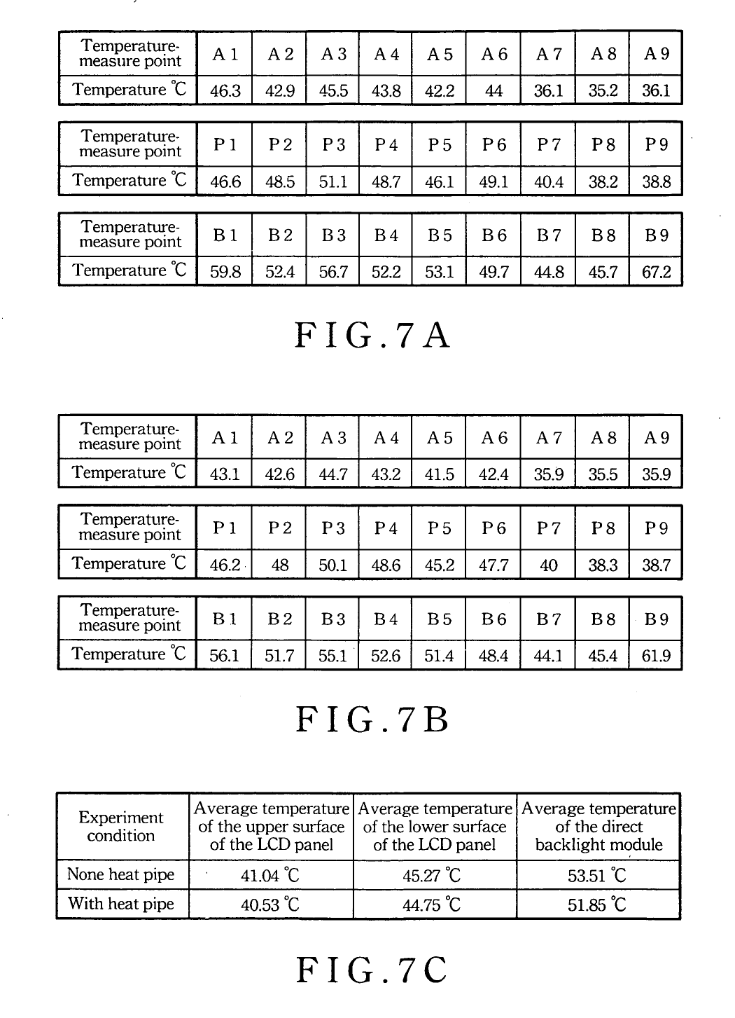

The testing results are tabled into FIG. 7A˜FIG. 7C, in which FIG. 7A shows the temperature data of the conventional LCD panel, FIG. 7B shows the temperature data of the LCD panel of the present invention, and FIG. 7C shows mean values of the data in FIG. 7A and FIG. 7B.

From FIG. 7C, it is found that the mean temperature of the direct backlight module of the present invention is lower than the conventional one that is lacking off heat-pipes. That is to say that the present invention can provide a better thermal performance to the direct backlight module.

Also from FIG. 7B and FIG. 7A, it is found that the temperature distribution of FIG. 7B is much evener than that of FIG. 7A. For instance, the temperature of the B9 point in FIG. 6C is hiked to 67.2° C. for the conventional LCD panel without the heat-pipes, but is lowered to 61.9° C. for the LCD panel having the heat-pipes. It is noted that the B9 point is within the range of the first predetermined portion 341 where the PCB is disposed; i.e., the B9 point is positioned in a location where a relative high temperature is expected. Apparently, by introducing the heat-pipe 41, a better temperature distribution in the LCD panel can be achieved.

Obviously, numerous modifications and variations of the present invention are possible in light of the above teachings. It is therefore to be understood that within the scope of the appended claims, the invention may be practiced otherwise than as specifically described herein.

We claim:

1. A direct backlight module, comprising:
a light source;
a substrate disposed on the substrate, a bottom surface of the substrate being divided into a first predetermined portion and a second predetermined portion;
a heat source disposed on the first predetermined portion and electrically connecting with the light source; and
at least a heat-pipe disposed on the bottom surface of the substrate to transfer heat from the first predetermined portion to the second predetermined portion.

2. A direct backlight module according to claim 1, wherein the heat source comprises a printed circuit board, an inverter, or a power supply.

3. A direct backlight module according to claim 1, wherein the heat-pipe is bent to a shape selected from the group of an “L” shape, an “N” shape, and a “W” shape.

4. A direct backlight module according to claim 1, wherein the heat-pipe comprises an elliptical cross section.

5. A direct backlight module according to claim 1, wherein the heat-pipe is disposed between the substrate and the heat source within a range corresponding to the first predetermined portion.

6. A direct backlight module according to claim 1, the heat-pipe is mounted to the substrate by at least one metal strip and a screw.

7. A direct backlight module according to claim 1, further comprising a heat sink, which is disposed on the first predetermined portion by contacting both the heat-pipe and the substrate.

8. A direct backlight module according to claim 7, wherein the heat sink is selected from the group of a copper mass, a aluminum mass, and a metal mass with a high conductive coefficient.

9. A direct backlight module according to claim 1, further comprising a heat conductive grease, which is disposed between the heat-pipe and the substrate within a range corresponding to the first predetermined portion.

10. A direct backlight module according to claim 1, wherein the light source is selected from the group of a CCFL and an LED.

11. A direct backlight module according to claim 1 further comprising a diffusion sheet, which is disposed above the light source.

12. A method of assembling a direct backlight module, comprising: providing a substrate, wherein a bottom surface of the substrate is divided into a first predetermined portion and a second predetermined portion;
disposing a heat-pipe on the bottom surface of the substrate; and
disposing a printed circuit board on the first predetermined portion.

13. A method according to claim 12 further comprising disposing a light source on the substrate.

14. A method according to claim 13 further comprising electrically connecting the light source and the printed circuit board.

15. A method according to claim 13 further comprising disposing a diffusion sheet above the light source.

16. A method according to claim 12 further comprising disposing a heat sink on the first predetermined portion by having the heat sink contact both the heat-pipe and the substrate.

17. A method according to claim 12 further comprising spreading a heat-conductive grease between the heat-pipe and the substrate.

18. A method according to claim 12 further comprising bending the heat-pipe before disposing the heat-pipe on the bottom surface of the substrate, wherein the heat-pipe is bent to a shape selected from the group of an “L” shape, an “N” shape, and a “W” shape.

19. A method according to claim 12 further comprising depressing the heat-pipe to comprise an elliptical cross section for increasing a contact area between the heat-pipe and the substrate.
